(19) United States
(12) Patent Application Publication
(10) Pub. No.: US 2025/0305124 A1
(43) Pub. Date: Oct. 2, 2025

(54) IN SITU TREATMENT OF MOLYBDENUM OXYHALIDE BYPRODUCTS IN SEMICONDUCTOR PROCESSING EQUIPMENT

(71) Applicant: Lam Research Corporation, Fremont, CA (US)

(72) Inventors: Panya WONGSENAKHUM, Fremont, CA (US); Joshua COLLINS, Sebastopol, CA (US); Sanjay GOPINATH, Fremont, CA (US); Kevin MADRIGAL, Campbell, CA (US); William LAFFERTY, Portland, OR (US); Matthew Bertram Edward GRIFFITHS, Campbell, CA (US); David Joseph MANDIA, Lake Oswego, OR (US)

(21) Appl. No.: 18/866,057

(22) PCT Filed: May 19, 2023
(86) PCT No.: PCT/US2023/023023

§ 371 Date: Nov. 14, 2024

Related U.S. Application Data
(60) Provisional application No. 63/365,182, filed on May 23, 2022.

(51) Int. Cl. C23C 16/44; C23C 16/14; C23C 16/455; H01L 21/3205

(52) U.S. Cl. CPC C23C 16/4405; C23C 16/14; C23C 16/4404; C23C 16/45553; C23C 16/45561; H01L 21/32051

(57) ABSTRACT

Provided are methods for increasing the efficiency of atomic layer deposition of molybdenum metal by in situ cleaning and decontamination of molybdenum oxyhalide precursor delivery lines to a deposition chamber. The cleaning process may take place by pre-treating the delivery lines with at least one surface passivating agent and/or by periodically treating the delivery lines with at least one corrosion inhibitor. Also provided are methods of removing oxidation from a deposited molybdenum film.

### INCORPORATION BY REFERENCE

A PCT Request Form is filed concurrently with this specification as part of the present application. Each application that the present application claims benefit of or priority to as identified in the concurrently filed Application Data Sheet is incorporated by reference herein in their entireties and for all purposes.

### BACKGROUND

Many semiconductor device fabrication processes involve deposition of metals such as molybdenum to form conductive films. During the deposition process, contaminants stemming from precursor decomposition, precursor impurities or precursor byproducts can clog the pipes or lines which transport the precursors into a deposition chamber. Due to clogging, gas flow in the lines becomes impeded or blocked altogether. To eliminate the contaminants, the deposition must be stopped, and the set up must be dismantled in order that the lines can be periodically replaced and/or removed to be cleaned. Such conventional contaminant removal practices are inefficient because they interrupt continuous operation of the deposition process. Therefore, there is a need for in situ techniques whereby undesirable contaminants can be cleared out of the delivery lines and/or prevented during the deposition process which do not involve inefficient downtimes for maintenance in order to remove molybdenum oxyhalide precursor contaminants.

The background description provided herein is for the purposes of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

### SUMMARY

Provided are methods for increasing the efficiency of atomic layer deposition of molybdenum metal by in situ cleaning of precursor delivery lines. The cleaning process may take place by pre-treating the delivery lines with a surface passivating agent and/or by periodically treating the delivery lines with a corrosion inhibitor.

Accordingly, in a first aspect, the present disclosure encompasses a method for deposition of molybdenum metal. In some embodiments, the method includes introducing a molybdenum oxyhalide precursor into a deposition chamber housing a semiconductor substrate via one or more precursor delivery lines; supplying the precursor delivery lines with periodic flows of at least one corrosion inhibitor; and reacting the molybdenum oxyhalide precursor with at least one reactant to form a molybdenum-containing layer on the semiconductor substrate.

In some embodiments, the at least one corrosion inhibitor comprises a chemical etchant.

In some embodiments, the chemical etchant is a tungsten halide or a molybdenum halide.

In some embodiments, the at least one corrosion inhibitor is chlorine, oxygen, fluorine, hydrogen chloride, hydrogen fluoride, chlorine trifluoride, nitrogen trifluoride or a combination thereof.

In some embodiments, the at least one corrosion inhibitor is oxygen and chlorine.

In some embodiments, the oxygen and chlorine are supplied to the precursor delivery lines sequentially or concomitantly.

In some embodiments, the at least one corrosion inhibitor is oxygen and fluorine.

In some embodiments, the oxygen and fluorine are supplied to the precursor delivery lines sequentially or concomitantly.

In some embodiments, the corrosion inhibitor is one of tungsten hexafluoride (WF₆), molybdenum pentachloride (MoCl₅), and water (H₂O).

In some embodiments, the molybdenum oxyhalide precursor is Mo_{q}OₙYₘ, where Y is a halogen; n is 1 or 2; q is 1, 2 or 4; and m is 1, 2 or 11.

In some embodiments, the molybdenum oxyhalide precursor is MoOF₄, Mo₄O₁₁I, MoO₂I, MoO₂Br₂, MoO₂Cl₂, MoOCl₄ or a combination thereof.

In some embodiments, the at least one reactant is hydrogen, ammonia, diborane, water, hydrogen sulfide, a thiol, an alcohol, an amine, hydrazine, silane, disilane or a combination thereof.

In a second aspect, the present disclosure encompasses a method deposition of molybdenum metal which includes providing a deposition chamber with one or more molybdenum oxyhalide precursor delivery lines; pre-treating the one or more molybdenum oxyhalide precursor delivery lines with at least one surface passivating agent to form one or more treated molybdenum oxyhalide precursor delivery lines; introducing one or more semiconductor substrates into the deposition chamber; introducing a molybdenum oxyhalide precursor into the deposition chamber via the one or more treated molybdenum oxyhalide precursor delivery lines; and reacting the molybdenum oxyhalide precursor with at least one reactant to form a molybdenum-containing layer on the semiconductor substrate.

In some embodiments, the one or more molybdenum oxyhalide precursor delivery lines is stainless steel or a nickel alloy.

In some embodiments, the molybdenum oxyhalide precursor is Mo_{q}OₙYₘ, where Y is a halogen; n is 1 or 2; q is 1, 2 or 4; and m is 1, 2 or 11.

In some embodiments, the molybdenum oxyhalide precursor is MoOF₄, Mo₄O₁₁I, MoO₂I, MoO₂Br₂, MoO₂Cl₂, MoOCl₄ or a combination thereof.

In some embodiments, the at least one reactant is hydrogen, ammonia, diborane, water, hydrogen sulfide, a thiol, an alcohol, an amine, hydrazine, silane, disilane or a combination thereof.

In some embodiments, the at least one surface passivating agent is fluorine.

In a third aspect, the present disclosure encompasses a method for atomic layer deposition of molybdenum metal that includes providing a deposition chamber with one or more molybdenum oxyhalide precursor delivery lines; pre-treating molybdenum oxyhalide precursor delivery lines with at least one surface passivating agent to form one or more treated molybdenum oxyhalide precursor delivery lines; introducing one or more semiconductor substrates into the deposition chamber;
introducing a molybdenum oxyhalide precursor into the deposition chamber via the one or more treated molybdenum oxyhalide precursor delivery lines; reacting the molybdenum oxyhalide precursor with at least one reactant to deposit a molybdenum-containing layer on the semiconductor substrate; and supplying molybdenum oxyhalide precursor delivery lines with periodic flows of at least one corrosion inhibitor.

In some embodiments, the one or more semiconductor substrates is a dummy wafer.

In some embodiments, the one or more molybdenum oxyhalide precursor delivery lines is stainless steel or a nickel alloy.

In some embodiments, the molybdenum oxyhalide precursor is Mo_{q}OₙYₘ, where Y is a halogen; n is 1 or 2; q is 1, 2 or 4; and m is 1, 2 or 11.

In some embodiments, the molybdenum oxyhalide precursor is MoOF₄, Mo₄O₁₁I, MoO₂I, MoO₂Br₂, MoO₂Cl₂, MoOCl₄ or a combination thereof.

In some embodiments, the at least one corrosion inhibitor is a chemical etchant.

In some embodiments, the chemical etchant is a tungsten halide or a molybdenum halide.

In some embodiments, the at least one corrosion inhibitor is chlorine, oxygen, fluorine, hydrogen chloride, hydrogen fluoride, chlorine trifluoride, nitrogen trifluoride or a combination thereof.

In some embodiments, the at least one corrosion inhibitor is one of tungsten hexafluoride (WF₆), molybdenum pentachloride (MoCl₅), and water (H₂O).

In some embodiments, the at least one corrosion inhibitor is oxygen and chlorine.

In some embodiments, the oxygen and chlorine are supplied to the one or more molybdenum oxyhalide precursor delivery lines sequentially or concomitantly.

In some embodiments, the at least one corrosion inhibitor is oxygen and fluorine.

In some embodiments, the oxygen and fluorine are supplied to the one or more molybdenum oxyhalide precursor delivery lines sequentially or concomitantly.

In a fourth aspect, the present disclosure encompasses a method that includes providing a semiconductor processing chamber with one or more molybdenum oxyhalide precursor delivery lines; and after processing one or more semiconductor substrates using a molybdenum oxyhalide precursor, supplying the one or more molybdenum oxyhalide precursor delivery lines with at least one corrosion inhibitor.

In a fifth aspect, the present disclosure encompasses a method that includes providing a semiconductor processing chamber with one or more molybdenum oxyhalide precursor delivery lines; and prior to processing one or more semiconductor substrates using a molybdenum oxyhalide, pre-treating the one or more molybdenum oxyhalide precursor delivery lines with at least one surface passivating agent.

In a sixth aspect, the present disclosure encompasses a method that includes providing a semiconductor processing chamber with one or more molybdenum oxyhalide precursor delivery lines; prior to processing one or more semiconductor substrates using a molybdenum oxyhalide, pre-treating the one or more molybdenum oxyhalide precursor delivery lines with at least one surface passivating agent; and after processing one or more semiconductor substrates using a molybdenum oxyhalide precursor, supplying the one or more molybdenum oxyhalide precursor delivery lines with at least one corrosion inhibitor.

In a seventh aspect the present disclosure encompasses a method that includes depositing molybdenum in a feature to fill the feature; and after filling the feature, exposing the deposited molybdenum to a chemical etchant to remove oxidation from the deposited molybdenum. In some embodiments, the chemical etchant is a tungsten halide or a molybdenum halide. In some embodiments, depositing molybdenum comprises sequentially introducing a molybdenum halide and a hydrogen co-reactant to a chamber housing the substrate. In some embodiments, the hydrogen co-reactant is a plasma generated from hydrogen (H₂) or other hydrogen-containing gas.

These and other aspects are described further below with reference to the drawings.

### BRIEF DESCRIPTION OF THE DRAWINGS

FIG. 1 is a process flow diagram depicting operations for methods of deposition of molybdenum metal in conjunction with periodic use of corrosion inhibitors in accordance with certain disclosed embodiments.

FIG. 2 is a process flow diagram depicting operations for methods of deposition of molybdenum metal in conjunction with pretreatment of precursor delivery lines with a surface passivating agent in accordance with certain disclosed embodiments.

FIG. 3 is a process flow diagram depicting operations for methods of deposition of molybdenum metal in conjunction with pretreatment of precursor delivery lines with a surface passivating agent and periodic use of corrosion inhibitors in accordance with certain disclosed embodiments.

FIG. 4 shows an example of the apparatus that may be used to perform the methods described herein in accordance with certain disclosed embodiments.

FIG. 5 shows an example of features filled with molybdenum (Mo).

FIG. 6 is a process flow diagram depicting operations for methods of deposition of molybdenum metal.

### DETAILED DESCRIPTION

In the following description, numerous specific details are set forth to provide a thorough understanding of the presented embodiments. The disclosed embodiments may be practiced without some or all of these specific details. In other instances, well-known process operations have not been described in detail to not unnecessarily obscure the disclosed embodiments. While the disclosed embodiments will be described in conjunction with the specific embodiments, it will be understood that it is not intended to limit the disclosed embodiments.

The implementations disclosed below describe deposition of a material on a substrate such as a wafer, substrate, or other work piece. The work piece may be of various shapes, sizes, and materials. In this application, the terms “semiconductor wafer,” “wafer,” “substrate,” “wafer substrate,” and “partially fabricated integrated circuit” are used interchangeably. One of ordinary skill in the art would understand that the term “partially fabricated integrated circuit” can refer to a silicon wafer during any of many stages of integrated circuit fabrication thereon. A wafer or substrate used in the semiconductor device industry typically has a diameter of 200 mm, or 300 mm, or 450 mm. Unless otherwise stated, the processing details recited herein (e.g., flow rates, power levels, etc.) are relevant for processing 300 mm diameter substrates, or for treating chambers that are configured to process 300 mm diameter substrates and can be scaled as appropriate for substrates or chambers of other sizes. In addition to semiconductor wafers, other work pieces that may be used implementations disclosed herein include various articles such as printed circuit boards and the like. The processes and apparatuses can be used in the fabrication of semiconductor devices, displays, LEDs, photovoltaic panels and the like.

By halide is meant an anion of F, Cl, Br or I.

As used herein, the term “about” means +/−10% of any recited value, unless otherwise specified. As used herein, this term modifies any recited value, range of values, or endpoints of one or more ranges.

As used herein, the terms “top,” “bottom,” “upper,” “lower,” “above,” and “below” are used to provide a relative relationship between structures. The use of these terms does not indicate or require that a particular structure must be located at a particular location in the apparatus.

As used herein, the phrase at least one of A, B, and C should be construed to mean a logical (A OR B OR C), using a non-exclusive logical OR, and should not be construed to mean ‘at least one of A, at least one of B, and at least one of C.

By “atomic layer deposition” (ALD) is meant a vapor deposition process in which deposition cycles, preferably a plurality of consecutive deposition cycles, are conducted in a process chamber (i.e. a deposition chamber). Typically during each cycle, the precursor is chemisorbed to a deposition surface (i.e. a substrate assembly surface or a previously deposited underlying surface such as material from a previous ALD cycle) forming a monolayer or sub-monolayer that does not readily react with additional precursor (i.e. a self-limiting reaction).

Thereafter, if necessary, a reactant (i.e. another precursor or reaction gas) may be introduced into the process chamber for use in converting the chemisorbed precursor to the desired material on the deposition surface. Typically, this reactant is capable of reaction with the already chemisorbed precursor. Further, purging steps may also utilized during each cycle to remove excess precursor from the process chamber and/or remove excess reactant and/or reaction by-products from the process chamber after conversion of the chemisorbed precursor.

By “deposition” or “vapor deposition” is meant a process in which a metal layer is formed on one or more surfaces of a substrate from vaporized precursor composition(s) including one or more metal containing compounds. The metal-containing compounds are vaporized and directed to and/or contacted with one or more surfaces of a substrate (i.e., semiconductor substrate or semiconductor assembly) placed in a deposition chamber. Typically, the substrate is heated. These metal containing compounds form a non-volatile, thin, uniform metal-containing layer on the surface(s) of the substrate. One operation of the method is one cycle, and the process can be repeated for as many cycles necessary to obtain the desired metal thickness.

By “chemical etchant” is meant any compound used to remove a material such as a layer, byproduct or contaminant from a surface.

By “contaminant” is meant any compound which may be an impurity, a decomposition product or a byproduct of the gas being delivered to the deposition chamber.

By “delivery lines” is meant any process equipment such as piping, tubes, or conduits that may be utilized to transport or convey a gas (e.g. reactant(s) and/or precursor(s)). In the semiconductor manufacturing process, precursor delivery lines may be used to transport precursors to a deposition chamber and may be formed from stainless steel or nickel alloys.

By “surface passivating agent” is meant an agent which renders a surface inert, such that the surface does not change properties when it interacts with other chemicals (e.g. reactants and/or precursors).

“Molybdenum metal” or “metallic molybdenum” as used herein, refers to material that consists essentially of molybdenum (Mo). Other elements (e.g., C, N, or O) can be present in molybdenum metal in small quantities (e.g., with a total content of less than about 15 atomic %, or less than about 10%, where hydrogen is not included in the calculation). “High purity molybdenum metal” as used herein refers to molybdenum metal that includes less than about 5% of other elements, such as less than about 1% of other elements, where hydrogen is not included in the calculation.

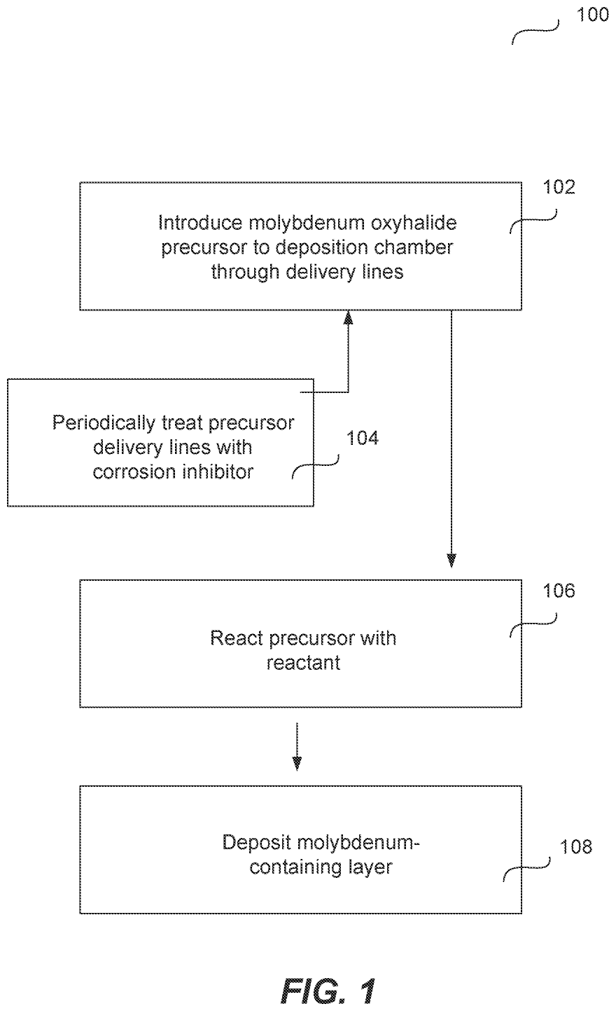

FIG. 1 schematically shows a non-limiting deposition process 100 for deposition of molybdenum metal including a cleaning mechanism whereby a corrosion inhibitor is periodically passed through molybdenum oxyhalide precursor delivery lines. In some embodiments, the deposition process is Atomic Layer Deposition. Atomic Layer Deposition (ALD) is a technique that deposits thin layers of material using sequential self-limiting reactions. ALD processes use surface-mediated deposition reactions to deposit films on a layer-by-layer basis in cycles. As an example, an ALD cycle may include the following operations: (i) delivery/adsorption of a precursor, (ii) purging of precursor from the chamber, (iii) delivery of a second reactant and optionally ignite plasma, and (iv) purging of byproducts from the chamber. The reaction between the second reactant and the adsorbed precursor to form a film on the surface of a substrate affects the film composition and properties, such as nonuniformity, stress, wet etch rate, dry etch rate, electrical properties (e.g., breakdown voltage and leakage current), etc. In ALD deposition of silicon oxide films, this reaction involves reacting oxygen plasma with carbon and nitrogen to form a gaseous species; oxidizing silicon to silicon oxide; eliminating trace carbon, nitrogen, and hydrogen impurities; and increasing bonding and densification of the film.

Unlike a chemical vapor deposition (CVD) technique, ALD processes use surface-mediated deposition reactions to deposit films on a layer-by-layer basis. In one example of an ALD process, a substrate surface that includes a population of surface-active sites is exposed to a gas phase distribution of a first precursor, such as a silicon-containing precursor, in a dose provided to a chamber housing a substrate. Molecules of this first precursor are adsorbed onto the substrate surface, including chemisorbed species and/or physisorbed molecules of the first precursor. It should be understood that when a compound is adsorbed onto the substrate surface as described herein, the adsorbed layer may include the compound as well as derivatives of the compound. For example, an adsorbed layer of a silicon-containing precursor may include the silicon-containing precursor as well as derivatives of the silicon-containing precursor. After a first precursor dose, the chamber is then evacuated to remove most or all of first precursor remaining in gas phase so that mostly or only the adsorbed species remain. In some implementations, the chamber may not be fully evacuated. For example, the reactor may be evacuated such that the partial pressure of the first precursor in gas phase is sufficiently low to mitigate a reaction. A second reactant, such as an oxygen-containing gas, is introduced to the chamber so that some of these molecules react with the first precursor adsorbed on the surface. In some processes, the second precursor reacts immediately with the adsorbed first precursor. In other embodiments, the second reactant reacts only after a source of activation is applied temporally. The chamber may then be evacuated again to remove unbound second reactant molecules. As described above, in some embodiments the chamber may not be completely evacuated. Additional ALD cycles may be used to build film thickness.

In some implementations, the ALD methods include plasma activation. As described herein, the ALD methods and apparatuses described herein may be conformal film deposition (CFD) methods, which are described generally in U.S. patent application Ser. No. 13/084,399 (now U.S. Pat. No. 8,728,956), filed Apr. 11, 2011, and titled “PLASMA ACTIVATED CONFORMAL FILM DEPOSITION,” and in U.S. patent application Ser. No. 13/084,305, filed Apr. 11, 2011, and titled “SILICON NITRIDE FILMS AND METHODS,” which are herein incorporated by reference in their entireties.

Returning to FIG. 1, in operation 102 a molybdenum oxyhalide precursor is delivered to a deposition chamber through delivery lines. In some embodiments, the delivery lines may be heated to a temperature of about 100° C. to about 300° C. In some embodiments, the delivery lines are high nickel alloys or electropolished stainless steel.

Molybdenum oxyhalide precursors are given by the formula MoO_{y}X_{z}, where X is a halogen (fluorine (F), chlorine (Cl), bromine (Br), or iodine (I)), and y and z are numbers greater than 0 such that MoO_{y}X_{z} forms a stable compound. Examples of molybdenum oxyhalides include molybdenum dichloride dioxide (MoO₂Cl₂), molybdenum tetrachloride oxide (MoOCl₄), molybdenum tetrafluoride oxide (MoOF₄), molybdenum dibromide dioxide (MoO₂Br₂), and the molybdenum iodides MoO₂I, and Mo₄O₁₁I. It should be understood that as used herein the term molybdenum oxyhalide precursor may refer to a molybdenum oxyhalide precursor as described above or a molybdenum-containing oxyhalide precursor that includes molybdenum, oxygen, a halide and one or more other elements. In some embodiments, molybdenum oxyhalide or molybdenum-containing oxyhalides may include multiple different halogens (e.g., F and Cl and/or I and/or Br, etc.).

The molybdenum halide or molybdenum oxyhalide precursor may also be a mixed halide precursor that has two or more halogens.

In FIG. 1, operation 104 is an in situ cleaning protocol utilized in some embodiments. As deposition occurs, after a pre-determined or pre-selected number of deposition cycles and/or a pre-determined or pre-selected number of layers or thickness of layers is achieved, the flow of molybdenum oxyhalide may be temporarily halted or slowed in order that a corrosion inhibitor may be flowed through the delivery lines to clear them of contaminants. In some embodiments, corrosion inhibitor may be flowed into the system when objective indicators from monitoring devices show it is necessary. For example, a temperature or pressure increase may indicate a clog that should be addressed. In some embodiments, the corrosion inhibitor may flow in the delivery lines concurrently with the molybdenum oxyhalide precursor.

In some embodiments, the contaminants may be precursor impurities, precursor byproducts or decomposition products. For example, when the precursor is molybdenum dichloride dioxide, byproducts can include MoO₃, MoOₓ suboxides and/or MoOₓCl_{y} complexes.

In some embodiments, the corrosion inhibitors are chemical etchants capable of reducing contaminant build up. For example, tungsten halides such as tungsten fluoride (WF₅) or tungsten hexafluoride (WF₆) or molybdenum halides such as molybdenum chloride ([MoCl₅]₂), molybdenum tetrafluoride (MoF₄), molybdenum pentafluoride (MoF₅), molybdenum hexafluoride (MoF₆), molybdenum bromide (MoBr₂), molybdenum dichloride (MoCl₂), molybdenum tribromide (MoBr₃), molybdenum trichloride (MoCl₃), molybdenum triiodide (MoI₃), molybdenum tetrabromide (MoBr₄) or molybdenum hexachloride (MoCl₆).

In some embodiments, the chemical etchant is chlorine (Cl₂), oxygen (O₂), fluorine (F₂), hydrogen chloride (HCl), hydrogen fluoride (HF), chlorine trifluoride (ClF₃), nitrogen trifluoride (NF₃), or a combination thereof. Examples of combinations include chlorine and oxygen and fluorine and oxygen. In some embodiments, a single corrosion inhibitor may be sufficiently effective. In some embodiments a combination of more than one corrosion inhibitors may be utilized. If a combination of etchants is utilized, they may be flowed through the delivery lines together (concomitantly), or sequentially (one following the other).

In some embodiments, liquid water (H₂O) is used as a corrosion inhibitor and chemical etchant. Delivery lines may be charged with liquid water. The water may then be purged by heating the delivery lines to remove the water. Water can help with removal of metal (e.g., iron, nickel, or chromium) contamination. Formation of hydrate (e.g., MoO₂Cl₂ hydrate) can be reversed by the purge.

In some embodiments, after the corrosion inhibitor is flowed through delivery lines, a molybdenum precursor may be flowed to passivate the lines.

In operation 106, to deposit molybdenum as illustrated in FIG. 1, the molybdenum precursor may be reacted with a reactant. Examples of reactants include hydrogen (H₂), silane (SiH₄), diborane (B₂H₆), germane (GeH₄), ammonia (NH₃), and hydrazine (N₂H₄).

For example, in some embodiments, a trench or via may be filled with molybdenum using a molybdenum oxyhalide precursor. A feature may be filled with molybdenum by atomic layer deposition (ALD) or chemical vapor deposition (CVD).

ALD is a surface-mediated deposition technique in which doses of a precursor and a reactant are sequentially introduced into a deposition chamber. One or more cycles of sequential doses of a molybdenum precursor and reactant may be used to deposit Mo. MoO₂Cl₂ may be used as a precursor and H₂ as a reducing agent. Doses of MoO₂Cl₂ and H₂ are sequentially introduced into the deposition chamber with a purge gas, such as argon, flowed between. For ALD, the temperature of the substrate and the pressure of the chamber may be controlled. For example, the substrate may be heated between 300° C. and 800° C., e.g., between 650° C. and 750° C. In some embodiments, the chamber may be pressurized between 10 Torr and 90 Torr, e.g., between 30 Torr and 50 Torr. In some embodiments, the temperature and/or pressure may be used to control the rate of reactions. In some embodiments, the temperature and/or pressure may be used to control selectivity.

In some embodiments, molybdenum fill may involve CVD. In a CVD process, the molybdenum precursor and reactant are in vapor phase together in the deposition chamber. Generally speaking, a CVD process fills a feature faster than an ALD process. In one example, the precursor may be a molybdenum oxychloride, such as MoO₂Cl₂, and is flowed into the chamber with a reactant, such as H₂. In this example, the wafer is simultaneously exposed to the precursor and reactant, which react and fill features with Mo.

In still some other embodiments, a feature may be filled using a pulsed CVD process. The pulsed CVD process continuously flows a reactant into a chamber while pulses of a precursor flow into the chamber. For example, H₂ gas may be flowed into the chamber and is continuously flowing into the chamber while the molybdenum-containing precursor is intermittently flowing into the chamber. The temperature of the substrate and pressure in the chamber may be controlled during a CVD operation.

Returning to FIG. 1, operation 108 is the deposition (or processing) of at least one molybdenum-containing layer. In an operation 108, if the desired thickness is achieved, the process can be ended. If the desired thickness has not been achieved, the process operations 102 and 106 (with 104 as needed) repeat for the number of cycles sufficient to achieve the desired metal thickness.

In some embodiments, operations 102, 106, and 108 may be performed repeatedly without an intervening operation 104 to deposit a molybdenum-containing layer on multiple substrates. Operation 104 may be performed without a substrate in the deposition chamber or with only a dummy wafer that does not include a partially fabricated device.

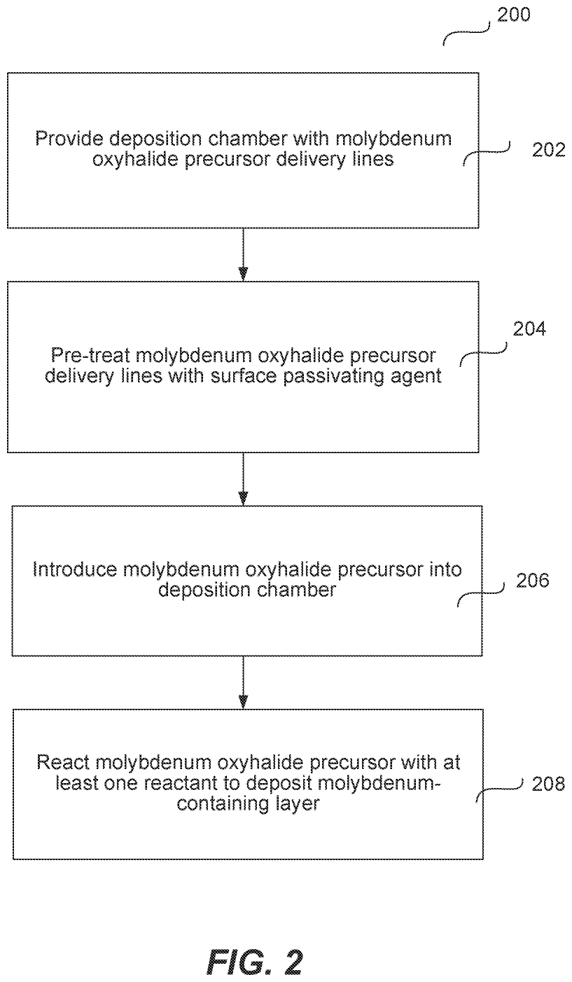

FIG. 2 schematically shows a non-limiting process 200 for deposition of molybdenum metal including an in situ cleaning mechanism whereby molybdenum oxyhalide precursor delivery lines are pre-treated with surface passivating agents to prevent buildup of contaminants.

In operation 202, a deposition chamber is provided with molybdenum precursor delivery lines. In some embodiments, the precursor is molybdenum oxyhalide.

In operation 204, precursor delivery lines are first treated (prior to processing) with at least one surface passivating agent before the precursor is transported via delivery lines to the deposition chamber in operation 206. In some embodiments, the surface passivating agent is fluorine. In some embodiments, the surface passivating agent is a fluorocarbon or a chlorofluorocarbon. In some embodiments, combinations of surface passivating agents may be utilized.

In some embodiments, the surface passivating agent coats the interior of the delivery lines, preventing buildup of contaminants.

In operation 208, the precursor and reactant react to deposit a molybdenum-containing layer.

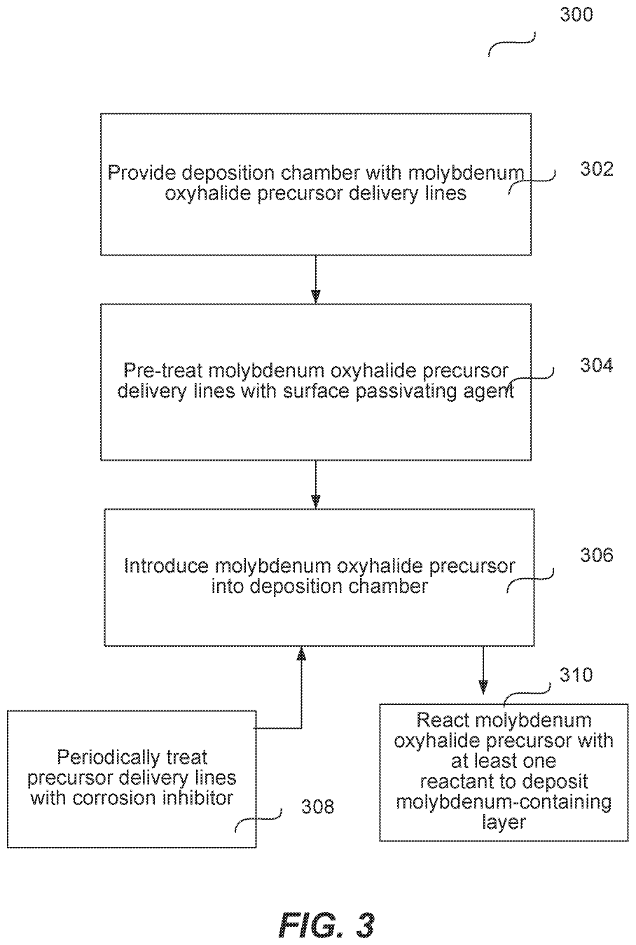

FIG. 3 schematically shows a non-limiting process 300 for deposition of molybdenum metal including a two-pronged in situ cleaning mechanism. In a deposition chamber configured with precursor delivery lines (operation 302), a pre-treatment of molybdenum oxyhalide precursor delivery lines with surface passivating agents takes place in operation 304; and then, corrosion inhibitors are periodically coursed through the delivery lines in operation 308 as needed as the cycles of deposition of layers (represented as operations 306 and 310) occurs.

In some embodiments, the in situ cleaning methods described herein may be utilized in conjunction with filters, moisture mitigation units or other purification equipment to ensure a robust system of semiconductor manufacturing.

As described above, the etching and surface passivation operations can be performed in situ without removal and replacement.

### Apparatus

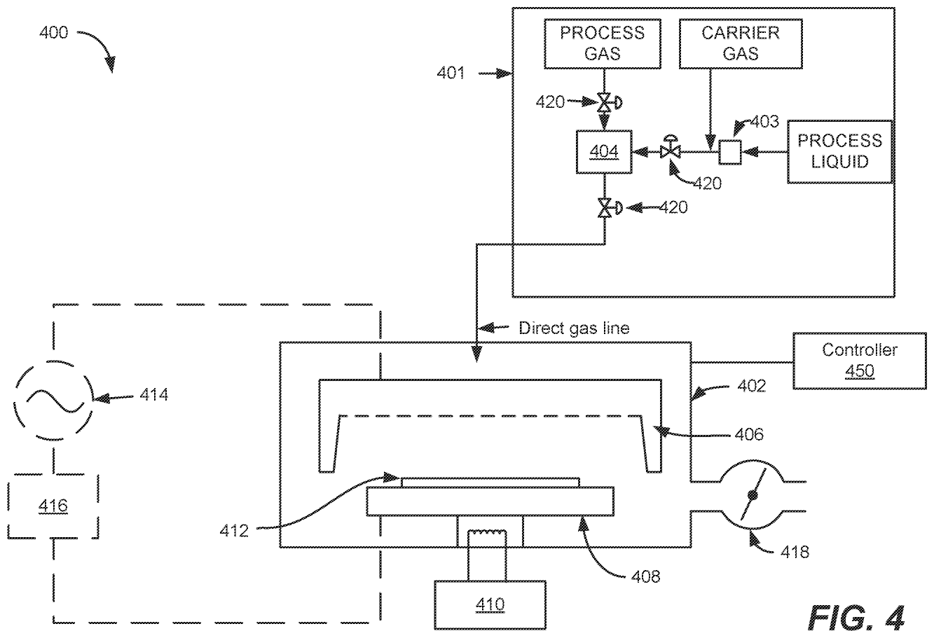

FIG. 4 depicts a schematic illustration of an embodiment of an ALD process station 400 having a process chamber 402 for maintaining a low-pressure environment. In some embodiments, a plurality of ALD process stations may be included in a common low-pressure process tool environment. In some embodiments, one or more hardware parameters of ALD process station 400, including those discussed in detail below, may be adjusted programmatically by one or more computer controllers 450. In some other embodiments, a process chamber may be a single station chamber.

ALD process station 400 fluidly communicates with reactant delivery system 401 for delivering process gases to a distribution showerhead 406. Reactant delivery system 401 includes a mixing vessel 404 for blending and/or conditioning process gases, such as a Mo precursor-containing gas, a hydrogen-containing gas, an argon or other carrier gas, or other reactant-containing gas, for delivery to showerhead 406. One or more mixing vessel inlet valves 420 may control introduction of process gases to the mixing vessel 404. In various embodiments, deposition of an initial Mo layer is performed in process station 400 and in some embodiments, other operations such as in-situ clean or Mo gap fill may be performed in the same or another station of the multi-station processing tool 400.

As an example, the embodiment of FIG. 4 includes a vaporization point 403 for vaporizing liquid reactant to be supplied to the mixing vessel 404. In some embodiments, vaporization point 403 may be a heated vaporizer. In some embodiments, a liquid precursor or liquid reactant may be vaporized at a liquid injector (not shown). For example, a liquid injector may inject pulses of a liquid reactant into a carrier gas stream upstream of the mixing vessel 404. In one embodiment, a liquid injector may vaporize the reactant by flashing the liquid from a higher pressure to a lower pressure. In another example, a liquid injector may atomize the liquid into dispersed microdroplets that are subsequently vaporized in a heated delivery pipe. Smaller droplets may vaporize faster than larger droplets, reducing a delay between liquid injection and complete vaporization. Faster vaporization may reduce a length of piping downstream from vaporization point 403. In one scenario, a liquid injector may be mounted directly to mixing vessel 404. In another scenario, a liquid injector may be mounted directly to showerhead 406.

In some embodiments, a liquid flow controller (LFC) upstream of vaporization point 403 may be provided for controlling a mass flow of liquid for vaporization and delivery to process chamber 402. For example, the LFC may include a thermal mass flow meter (MFM) located downstream of the LFC. A plunger valve of the LFC may then be adjusted responsive to feedback control signals provided by a proportional-integral-derivative (PID) controller in electrical communication with the MFM. However, it may take one second or more to stabilize liquid flow using feedback control. This may extend a time for dosing a liquid reactant. Thus, in some embodiments, the LFC may be dynamically switched between a feedback control mode and a direct control mode. In some embodiments, this may be performed by disabling a sense tube of the LFC and the PID controller.

Showerhead 406 distributes process gases toward substrate 412. In the embodiment shown in FIG. 4, the substrate 412 is located beneath showerhead 406 and is shown resting on a pedestal 408. Showerhead 406 may have any suitable shape and may have any suitable number and arrangement of ports for distributing process gases to substrate 412.

In some embodiments, pedestal 408 may be raised or lowered to expose substrate 412 to a volume between the substrate 412 and the showerhead 406. In some embodiments, pedestal 408 may be temperature controlled via heater 410. Pedestal 408 may be set to any suitable temperature, such as between about 300° C. and about 500° C. during operations for performing various disclosed embodiments. It will be appreciated that, in some embodiments, pedestal height may be adjusted programmatically by a suitable computer controller 450. At the conclusion of a process phase, pedestal 408 may be lowered during another substrate transfer phase to allow removal of substrate 412 from pedestal 408.

In some embodiments, a position of showerhead 406 may be adjusted relative to pedestal 408 to vary a volume between the substrate 412 and the showerhead 406. Further, it will be appreciated that a vertical position of pedestal 408 and/or showerhead 406 may be varied by any suitable mechanism within the scope of the present disclosure. In some embodiments, pedestal 408 may include a rotational axis for rotating an orientation of substrate 412. It will be appreciated that, in some embodiments, one or more of these example adjustments may be performed programmatically by one or more suitable computer controllers 450. The computer controller 450 may include any of the features described below with respect to controller 450 of FIG. 4.

In some embodiments where plasma may be used as discussed above, showerhead 406 and pedestal 408 electrically communicate with a radio frequency (RF) power supply 414 and matching network 416 for powering a plasma. In some embodiments, the plasma energy may be controlled by controlling one or more of a process station pressure, a gas concentration, an RF source power, an RF source frequency, and a plasma power pulse timing. For example, RF power supply 414 and matching network 416 may be operated at any suitable power to form a plasma having a desired composition of radical species. Likewise, RF power supply 414 may provide RF power of any suitable frequency. In some embodiments, RF power supply 414 may be configured to control high- and low-frequency RF power sources independently of one another. Example low-frequency RF frequencies may include, but are not limited to, frequencies between 0 kHz and 900 kHz. Example high-frequency RF frequencies may include, but are not limited to, frequencies between 1.8 MHz and 2.45 GHz, or greater than about 13.56 MHz, or greater than 27 MHz, or greater than 80 MHz, or greater than 60 MHz. It will be appreciated that any suitable parameters may be modulated discretely or continuously to provide plasma energy for the surface reactions.

In some embodiments, the plasma may be monitored in-situ by one or more plasma monitors. In one scenario, plasma power may be monitored by one or more voltage, current sensors (e.g., VI probes). In another scenario, plasma density and/or process gas concentration may be measured by one or more optical emission spectroscopy sensors (OES). In some embodiments, one or more plasma parameters may be programmatically adjusted based on measurements from such in-situ plasma monitors. For example, an OES sensor may be used in a feedback loop for providing programmatic control of plasma power. It will be appreciated that, in some embodiments, other monitors may be used to monitor the plasma and other process characteristics. Such monitors may include, but are not limited to, infrared (IR) monitors, acoustic monitors, and pressure transducers.

In some embodiments, instructions for a controller 450 may be provided via input/output control (IOC) sequencing instructions. In one example, the instructions for setting conditions for a process phase may be included in a corresponding recipe phase of a process recipe. In some cases, process recipe phases may be sequentially arranged, so that all instructions for a process phase are executed concurrently with that process phase. In some embodiments, instructions for setting one or more reactor parameters may be included in a recipe phase. For example, a first recipe phase may include instructions for setting a flow rate of an inert and/or a reactant gas (e.g., a Mo precursor), instructions for setting a flow rate of a carrier gas (such as argon), and time delay instructions for the first recipe phase. A second, subsequent recipe phase may include instructions for modulating or stopping a flow rate of an inert and/or a reactant gas, and instructions for modulating a flow rate of a carrier or purge gas and time delay instructions for the second recipe phase. A third recipe phase may include instructions for modulating a flow rate of a second reactant gas such as H₂, instructions for modulating the flow rate of a carrier or purge gas, instructions for igniting a plasma, and time delay instructions for the third recipe phase. A fourth, subsequent recipe phase may include instructions for modulating or stopping a flow rate of an inert and/or a reactant gas, and instructions for modulating a flow rate of a carrier or purge gas and time delay instructions for the fourth recipe phase. It will be appreciated that these recipe phases may be further subdivided and/or iterated in any suitable way within the scope of the present disclosure.

Further, in some embodiments, pressure control for process station 400 may be provided by butterfly valve 418. As shown in the embodiment of FIG. 4, butterfly valve 418 throttles a vacuum provided by a downstream vacuum pump (not shown). However, in some embodiments, pressure control of process station 400 may also be adjusted by varying a flow rate of one or more gases introduced to the process station 400.

Also shown in FIG. 4 is a delivery line treatment gas source 430. The delivery line treatment gas source 430 can include one or more corrosion inhibitor and/or surface passivation gas sources as described above. It is configured to supply the delivery line treatment gas or gases to the process gas delivery lines as described above. The controller can include instructions for performing periodic in-situ etch and/or surface passivation. The instructions can include instructions for heating the delivery lines as discussed above.

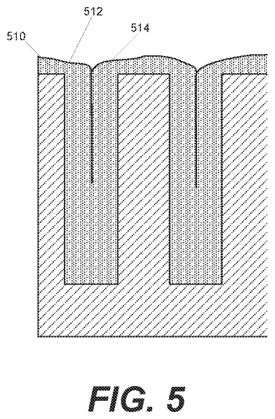

Another aspect of the disclosure relates to using WF₆ or other chemical etchant to remove oxidized molybdenum after deposition on a substrate. FIG. 5 shows an example of features including molybdenum 510 deposited to fill the features. In some embodiments, molybdenum oxide may be present on exposed surfaces 512 and, if a seam 514 is present, in a seam 514. Exposing the filled feature to a chemical etchant as described removes the oxidation.

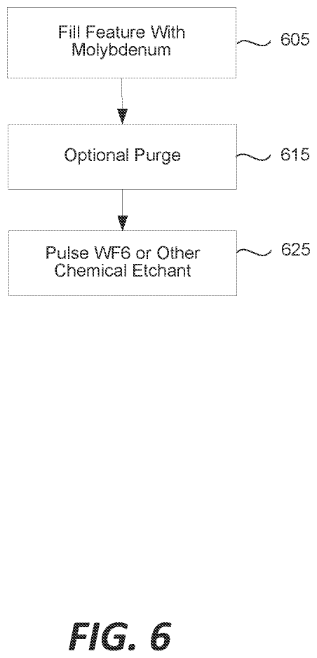

FIG. 6 is a flow diagram according to certain embodiments. A feature is filled with molybdenum in an operation 605. Filling a feature with molybdenum is described above with respect to operation 108 of FIG. 1. One example of a feature is a hole or via in a semiconductor substrate or a layer on the semiconductor substrate. For example, the feature may be formed at least partially in a dielectric layer. In some embodiments, a feature may have an aspect ratio of at least about 2:1, at least about 4:1, at least about 6:1, at least about 10:1, at least about 25:1, or higher.

As described above, a feature may be filled with molybdenum by atomic layer deposition (ALD) or chemical vapor deposition (CVD). Thermal ALD or plasma enhanced ALD (PEALD) may be used. Similarly, thermal CVD or plasma enhanced CVD (PECVD) may be used.

For example, Mo₂Cl₂ or MoCl₅ may be used as a precursor and H₂ as a reducing agent. Doses of MoCl₅ and H₂ are sequentially introduced into the deposition chamber with a purge gas, such as argon, flowed between. For ALD, the temperature of the substrate and the pressure of the chamber may be controlled. In a PEALD process, the Mo precursor may be alternated with a plasma generated from H₂ gas.

In some embodiments, molybdenum fill may involve CVD. In a CVD process, the molybdenum precursor and reactant are in vapor phase together in the deposition chamber. Generally speaking, a CVD process fills a feature faster than an ALD process. In one example, the precursor may be a molybdenum oxychloride, such as MoO₂Cl₂, and is flowed into the chamber with a reactant, such as H₂. In this example, the wafer is simultaneously exposed to the precursor and reactant, which react and fill features with Mo.

In still some other embodiments, a feature may be filled using a pulsed CVD process. The pulsed CVD process continuously flows a reactant into a chamber while pulses of a precursor flow into the chamber. For example, H₂ gas may be flowed into the chamber and is continuously flowing into the chamber while the molybdenum-containing precursor is intermittently flowing into the chamber. The temperature of the substrate and pressure in the chamber may be controlled during a CVD operation. Any of the above-described processes may use any appropriate reducing agent including H₂, silane (SiH₄), and/or diborane (B₂H₆) or a plasma generated from same.

In some embodiments, particularly if the deposition is performed at lower temperatures (such as for a plasma-based deposition), residual oxidation may be present. This can be in the form of molybdenum oxide (MoOₓ) and/or hydrated molybdenum precursor (e.g., MoO₂Cl₂·H₂O).

In an operation 615, an optional purge is performed. Then, in an operation 625, WF₆ or other chemical etchant as described herein (e.g., MoCl₅) is introduced into a chamber housing the substrate including the filled feature. This may be referred to as a dose or soak and removes the oxidation. The methods may be performed in an apparatus as described above with reference to FIG. 4.

The foregoing describes implementation of disclosed embodiments in a single or multi-chamber semiconductor processing tool. The apparatus and process described herein may be used in conjunction with lithographic patterning tools or processes, for example, for the fabrication or manufacture of semiconductor devices, displays, LEDs, photovoltaic panels, and the like. Typically, though not necessarily, such tools/processes will be used or conducted together in a common fabrication facility. Lithographic patterning of a film typically includes some or all of the following steps, each step provided with a number of possible tools: (1) application of photoresist on a workpiece, i.e., substrate, using a spin-on or spray-on tool; (2) curing of photoresist using a hot plate or furnace or UV curing tool; (3) exposing the photoresist to visible or UV or x-ray light with a tool such as a wafer stepper; (4) developing the resist so as to selectively remove resist and thereby pattern it using a tool such as a wet bench; (5) transferring the resist pattern into an underlying film or workpiece by using a dry or plasma-assisted etching tool; and (6) removing the resist using a tool such as an RF or microwave plasma resist stripper.

### CONCLUSION

Although the foregoing embodiments have been described in some detail for purposes of clarity of understanding, it will be apparent that certain changes and modifications may be practiced within the scope of the appended claims. It should be noted that there are many alternative ways of implementing the processes, systems, and apparatus of the present embodiments. Accordingly, the present embodiments are to be considered as illustrative and not restrictive, and the embodiments are not to be limited to the details given herein.

1. A method for deposition of molybdenum metal comprising:
introducing a molybdenum oxyhalide precursor into a deposition chamber housing a semiconductor substrate via one or more precursor delivery lines;
supplying the precursor delivery lines with periodic flows of at least one corrosion inhibitor; and
reacting the molybdenum oxyhalide precursor with at least one reactant to form a molybdenum-containing layer on the semiconductor substrate.

2. The method of claim 1, wherein the at least one corrosion inhibitor comprises a chemical etchant.

3. The method of claim 2, wherein the chemical etchant comprises a tungsten halide or a molybdenum halide.

4. The method of claim 1, wherein the at least one corrosion inhibitor comprises chlorine, oxygen, fluorine, hydrogen chloride, hydrogen fluoride, chlorine trifluoride, nitrogen trifluoride or a combination thereof.

5. The method of claim 4, wherein the at least one corrosion inhibitor comprises oxygen and chlorine.

6. The method of claim 5, wherein the oxygen and chlorine are supplied to the precursor delivery lines sequentially or concomitantly.

7. The method of claim 4, wherein the at least one corrosion inhibitor comprises oxygen and fluorine.

8. The method of claim 7, wherein the oxygen and fluorine are supplied to the precursor delivery lines sequentially or concomitantly.

9. The method of claim 1, wherein the molybdenum oxyhalide precursor is Mo_{q}OₙYₘ, wherein Y is a halogen; n is 1 or 2; q is 1, 2 or 4; and m is 1, 2 or 11.

10. The method of claim 9, wherein the molybdenum oxyhalide precursor comprises MoOF₄, Mo₄O₁₁I, MoO₂I, MoO₂Br₂, MoO₂Cl₂, MoOCl₄ or a combination thereof and/or the at least one reactant comprises hydrogen, ammonia, diborane, water, hydrogen sulfide, a thiol, an alcohol, an amine, hydrazine, silane, disilane or a combination thereof.

11. The method of claim of 1, wherein the corrosion inhibitor is one of tungsten hexafluoride (WF₆), molybdenum pentachloride (MoCl₅), and water (H₂O).

12. A method for deposition of molybdenum metal comprising:
providing a deposition chamber with one or more molybdenum oxyhalide precursor delivery lines;
pre-treating the one or more molybdenum oxyhalide precursor delivery lines with at least one surface passivating agent to form one or more treated molybdenum oxyhalide precursor delivery lines;
introducing one or more semiconductor substrates into the deposition chamber;
introducing a molybdenum oxyhalide precursor into the deposition chamber via the one or more treated molybdenum oxyhalide precursor delivery lines; and
reacting the molybdenum oxyhalide precursor with at least one reactant to form a molybdenum-containing layer on the semiconductor substrate.

13. The method of claim 12, wherein the one or more molybdenum oxyhalide precursor delivery lines comprises stainless steel or nickel alloys.

14. The method of claim 12, wherein the molybdenum oxyhalide precursor is Mo_{q}OₙYₘ, wherein Y is a halogen; n is 1 or 2; q is 1, 2 or 4; and m is 1, 2 or 11.

15. The method of claim 14, wherein the molybdenum oxyhalide precursor comprises MoOF₄, Mo₄O₁₁I, MoO₂I, MoO₂Br₂, MoO₂Cl₂, MoOCl₄ or a combination thereof.

16. The method of claim 12, wherein the at least one reactant comprises hydrogen, ammonia, diborane, water, hydrogen sulfide, a thiol, an alcohol, an amine, hydrazine, silane, disilane or a combination thereof.

17. The method of claim 12, wherein the at least one surface passivating agent is fluorine.

18. A method for atomic layer deposition of molybdenum metal comprising:
providing a deposition chamber with one or more molybdenum oxyhalide precursor delivery lines;
pre-treating molybdenum oxyhalide precursor delivery lines with at least one surface passivating agent to form one or more treated molybdenum oxyhalide precursor delivery lines;
introducing one or more semiconductor substrates into the deposition chamber;
introducing a molybdenum oxyhalide precursor into the deposition chamber via the one or more treated molybdenum oxyhalide precursor delivery lines;
reacting the molybdenum oxyhalide precursor with at least one reactant to deposit a molybdenum-containing layer on the semiconductor substrate; and
supplying molybdenum oxyhalide precursor delivery lines with periodic flows of at least one corrosion inhibitor.

19. The method of claim 18, wherein the one or more semiconductor substrates comprises a dummy wafer.

20. The method of claim 18, wherein the one or more molybdenum oxyhalide precursor delivery lines comprise stainless steel or nickel alloys.

21.-37. (canceled)
